(19) United States
(12) Patent Application Publication
(10) Pub. No.: US 2023/0284406 A1
(43) Pub. Date: Sep. 7, 2023

(54) LATCHING ASSEMBLIES FOR ELECTRONIC DEVICES

(71) Applicant: HEWLETT-PACKARD DEVELOPMENT COMPANY, L.P., Spring, TX (US)

(72) Inventors: Cheng-Yi Yang, Taipei City (TW); Timothy Arthur Kubicki, Spring, TX (US); Owen P. Columbus, Spring, TX (US); Matthew William Tivnon, Spring, TX (US)

(73) Assignee: HEWLETT-PACKARD DEVELOPMENT COMPANY, L.P., Spring, TX (US)

(21) Appl. No.: 17/801,405

(22) PCT Filed: Jan. 30, 2020
(86) PCT No.: PCT/US2020/015887

§ 371 Date: Aug. 22, 2022

(51) Int. Cl. H05K 5/02; H05K 7/14

(52) U.S. Cl. CPC H05K 5/0221; H05K 7/1411

(57) ABSTRACT

Example latching assemblies and electronic devices including the latching assemblies are disclosed. In an example, an electronic device includes a housing including a cavity to receive a peripheral device therein. In addition, the electronic device includes a latching assembly disposed within the housing. The latching assembly includes a latch biased toward the cavity to engage with the peripheral device, and a block. Displacement of the block is to slidingly engage the block along the latch and thereby withdraw the latch from the cavity.

### BACKGROUND

An electronic device may include a peripheral device (or a plurality of peripheral devices) that are to provide additional functionality to the electronic device during operations. For instance, an electronic device may comprise an all-in-one computer utilized as a retail point-of-sale terminal (e.g., cash register), and the peripheral device(s) may comprise credit card readers, a customer facing display, and/or a receipt printer, etc., that may be used in conjunction with the host electronic device.

### BRIEF DESCRIPTION OF THE DRAWINGS

Various examples will be described below referring to the following figures:

FIGS. 1 and 2 are schematic views of a peripheral device engaged within a cavity of an electronic device via a latching assembly according to some examples;

FIG. 3 is a schematic bottom view of an example latch assembly according to some examples;

FIGS. 4 and 5 are schematic cross-sectional views taken along section A-A of the latching assembly of FIG. 3 disposed within an electronic device according to some examples;

FIGS. 6 and 7 are schematic cross-sectional views taken along section B-B of the latching assembly of FIG. 3 disposed within an electronic device according to some examples; and

FIGS. 8 and 9 are schematic cross-sectional views of a latching assembly for use within an electronic device according to some examples.

### DETAILED DESCRIPTION

In the figures, certain features and components disclosed herein may be shown exaggerated in scale or in somewhat schematic form, and some details of certain elements may not be shown in the interest of clarity and conciseness. In some of the figures, in order to improve clarity and conciseness, a component or an aspect of a component may be omitted.

In the following discussion and in the claims, the terms “including” and “comprising” are used in an open-ended fashion, and thus should be interpreted to mean “including, but not limited to . . . .” Also, the term “couple” or “couples” is intended to be broad enough to encompass both indirect and direct connections. Thus, if a first device couples to a second device, that connection may be through a direct connection or through an indirect connection via other devices, components, and connections. In addition, as used herein, the terms “axial” and “axially” generally refer to positions along or parallel to a central or longitudinal axis (e.g., central axis of a body or a port), while the terms “radial” and “radially” generally refer to positions located or spaced to the side of the central or longitudinal axis.

As used herein, including in the claims, the word “or” is used in an inclusive manner. For example, “A or B” means any of the following: “A” alone, “B” alone, or both “A” and “B.” In addition, when used herein including the claims, the word “generally” or “substantially” means within a range of plus or minus 10% of the stated value. As used herein, the term “electronic device,” refers to a device that is to carry out machine-readable instructions, and may include internal components, such as, processors, power sources, memory devices, etc. For example, a computing device may include, among other things, a personal computer, a smart phone, a tablet computer, a laptop computer, all-in-one computer, a personal data assistant, etc. As used herein a “peripheral device,” refers to a device or assembly that is to carry out a function or plurality of functions. In some instances, the function(s) carried out by the peripheral device may be performed in concert with and/or under the direction or control of a host electronic device. In addition, a peripheral device may, in some cases, comprise an “electronic device” as defined herein. Thus, in some circumstances, a peripheral device may carry out machine-readable instructions and may include components, such as processors, power sources, memory devices, etc.

As previously described, an electronic device (e.g., such as an all-in-one computer utilized at a retail point-of-sale terminal) may include a number of peripheral devices that are coupled to the electronic device and are to perform a number of functions related to the general operation of the electronic device. In many instances, such peripheral devices may be attached or mounted to the housing of the host electronic device itself. However, in some cases, the attachment of mounting of the peripheral devices is accomplished via screws or other mounting devices that call for the use of suitable tools (e.g., a screw driver). In addition, access to the attachment points (e.g., screw holes) on the electronic device for the mounting devices may necessitate removal of a cover (or multiple covers) from the electronic device housing. As a result, attachment of peripheral devices to the host electronic device may be complex and time-consuming. Accordingly, the examples disclosed herein include latching assemblies for facilitating relatively simple attachment and detachment procedures for a peripheral device to a host electronic device.

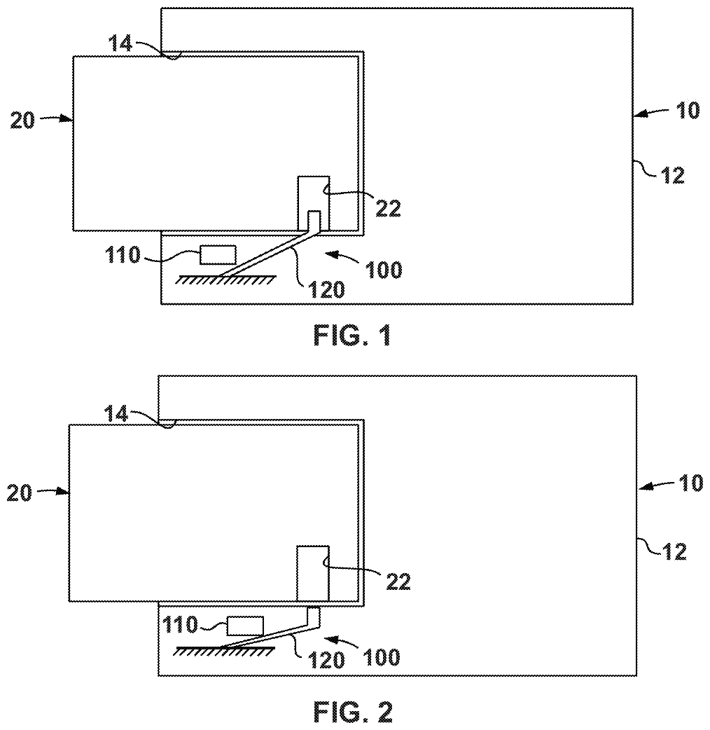

Referring now to FIGS. 1 and 2, an electronic device 10 and peripheral device 20 are shown. In this example, electronic device 10 comprises an all-in-one computer that is utilized as a point-of-sale terminal. Generally speaking, the electronic device 10 includes a housing 12 that defines a cavity 14, that is to receive the peripheral device 20 (or a portion thereof) therein during operations. Electronic device 10 may include other components, such as, for instance, a display and/or a user input device (e.g., keyboard, touch sensitive surface, etc.); however, these components are not specifically shown so as to simplify the figures. Peripheral device 20 may comprise a single or multi-functional peripheral device. For instance, in some examples, the peripheral device 20 may comprise a receipt printer, a customer-facing display, and/or a credit card reader.

A latching assembly 100 is disposed within the housing 12 of electronic device 10, proximate the cavity 14. In some examples, latching assembly 100 may form or define a portion of the cavity 14. While the details of examples of latching assembly 100 are described in more detail below, generally speaking latching assembly 100 includes a latch 120 and a block 110. The latch 120 is biased into the cavity 14. For instance, latch 120 may comprise a flat spring that is biased inward toward cavity 14 during operations.

As best shown in FIG. 1, when a peripheral device 20 is installed within cavity 14, the latch 120 is biased into engagement with a recess 22 or other suitable latching feature on peripheral device 20 to secure and hold the peripheral device 20 within cavity 14. Referring now to FIG. 2, when it is desired to remove the peripheral device 20 from cavity 14, block 110 is displaced (e.g., via a button or other suitable tool or mechanism) relative to the latch 120 so that block 110 slidingly engages with latch 120 to thereby withdraw latch 120 from recess 22 and cavity 14. Once latch 120 is withdrawn from recess 22 and cavity 14, peripheral device 20 may be removed (e.g., pulled) from cavity 14. Further details of examples of latching assembly 100 are now described below.

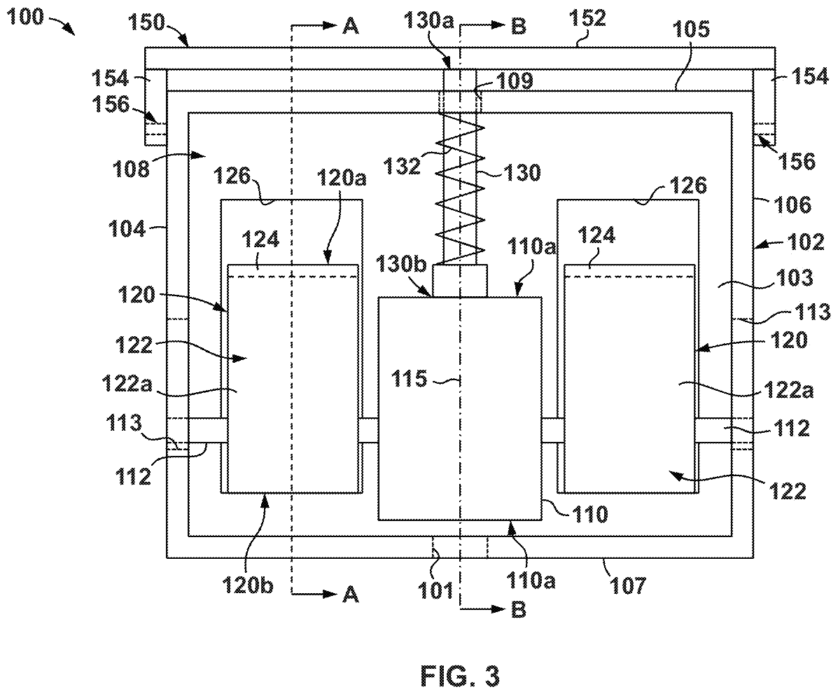

Referring now to FIG. 3, an example latching assembly 100 is shown that may be used within electronic device 10 in FIGS. 1 and 2. Latching assembly 100 generally includes block 110, a pair of latches 120, a frame 102, and an ejector 150.

In this example, frame 102 is a generally rectangular cup-shaped member that includes a planar base surface 103, and a plurality of walls 104, 105, 106, 107 extending from an outer periphery of the base surface 103. In particular, the walls 104, 106 oppose one another across base surface 103, and walls 105, 107 oppose one another across base surface 103. In addition, the walls 104, 106 extend between the walls 105, 107, and the walls 105, 107 extend between the walls 104, 106 across based surface 103. Together, the base surface 103 and walls 104, 105, 106, 107 form or define a receptacle 108 that receives the block 110 (which will be described in more detail below).

A pair of openings or apertures 126 is formed in the base surface 103. As will be described in more detail below, the apertures 126 receive latches 120 therethrough to selectively secure a peripheral device (e.g., peripheral device 20) within a cavity (e.g., cavity 14) of an electronic device (e.g., electronic device 10) during operations.

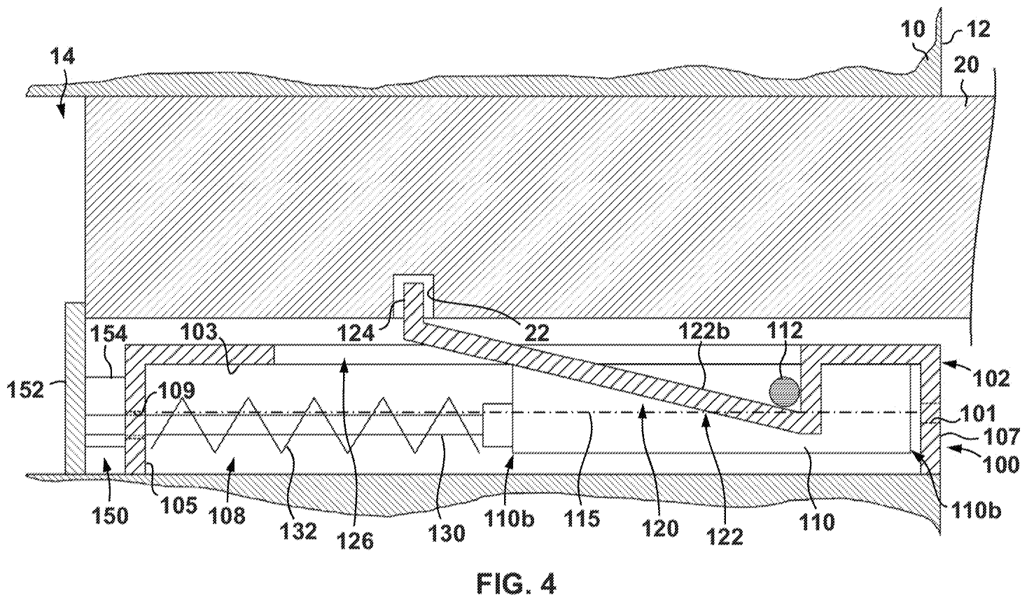

Referring still to FIG. 3, latches 120 are coupled to base surface 103 of frame 102. In some examples, latches 120 are integrally formed with the material forming base surface 103 such that latches 120 and base surface 103 are formed as a one-piece, continuous, monolithic body. Referring briefly to FIGS. 3 and 4, each latch 120 includes a first end 120a, a second end 120b opposite first end 120a, a foot 124 disposed at second end 120b, and a ramped portion 122 extending from foot 124 toward first end 120a. Referring briefly to FIG. 4, the ramped portion 122 extends through aperture 126 so that foot 124 is generally biased through aperture 126 in base surface 103. As is also best shown in FIG. 4, the ramped portion 122 includes a first side or surface 122a that generally faces inward toward receptacle 108, and a second side or surface 122b opposite first side 122a that faces outward or away from receptacle 108.

In the example of FIG. 4, the latching assembly 100, and particularly the frame 102, for a portion of the cavity 14 within electronic device 10. However, in other examples, the latching assembly 100 may be within the electronic device 10, adjacent the cavity 14, without forming any portion of the cavity 14, itself. In either case, the position of the latching assembly 100 relative to the cavity 14 is such that the ramped portions 122 of latches 120 are to bias the feet 124 of latches 120 generally into the cavity 14 as generally described above with respect to the FIGS. 1 and 2.

Referring again to FIGS. 3 and 4, block 110 is generally shaped as a rectangular parallelepiped and includes a central or longitudinal axis 115, a first end 110a, and a second end 110b opposite first end 110a. A pair of arms 112 extends radially outward from opposing sides of block 110, axially between the first end 110a and second end 110b. The arms 112 may be coupled to the block 110 or formed as a single-piece, monolithic body with the block 110. The radially outermost ends 112a of arms 112 are received within slots 113 formed in the walls 104, 106. In addition, as best shown in FIG. 4, the arms 112 are engaged with the second side 122b of ramped surfaces 122 of latches 120.

Ejector 150 includes an engagement member 152 and a pair of arms 154. Each arm 154 is pivotably coupled to the frame 102 at a corresponding pinned connection 156. Latching assembly 100 also includes a rod 130 that includes a first end 130a, and second end 130b opposite first end 130a. The rod 130 is inserted within receptacle 108 of frame 102 such that rod 130 extends axially between engagement member 152 of ejector 150 and first end 110a of block 110. In particular, rod 130 extends through an aperture 109 in wall 105 of frame 102 so that first end 130a is engaged with engagement member 152 of ejector 150 and second end 130b is engaged with first end 110a of block 110. A biasing member 132, which in this example comprises a coiled spring, is disposed about rod 130 and bears against wall 105 of frame 102 so as to bias second end 130b of rod 130 toward first end 110a of block 110 during operations. Because second end 130b of rod 130 is engaged with first end 110a of block 110, the biasing member 132 biases the block 110 axially (e.g., with respect to axis 115) toward wall 107 and away from wall 105 within receptacle 108.

Referring now to FIG. 4, during operations, a peripheral device 20 is inserted within cavity 14 of electronic device 10 as previously described. As best shown in FIG. 4, once peripheral device 20 is fully seated within cavity 14, the feet 124 of latches 120 (note: one of the latches 120 is not visible in the view of FIG. 4) are biased into corresponding recesses 22 on peripheral device 20 as previously described. During the initial insertion of the peripheral device 20 within cavity 14, the outer surface of the peripheral device 20 may engage with the feet 124 of latches 120 so as to deflect the latches 120 out of or away from cavity 14 until the recess(es) are aligned with feet 124, at which point the feet 124 are allowed to spring into the recess(es) via the bias provided by ramped portions 122.

In addition, in this example, when peripheral device 20 is fully seated within cavity 14, engagement member 152 of ejector 150 is engaged with the peripheral device 20. Thus, attachment of the peripheral device 20 involves simply inserting the peripheral device 20 into cavity 14 until latches 120 on latching assembly 100 spring or bias into recesses 22 to automatically secure peripheral device 20 within cavity 14 during operations. In other words, the latching assembly 100 allows for a tool-less attachment of peripheral device 20 to electronic device 10.

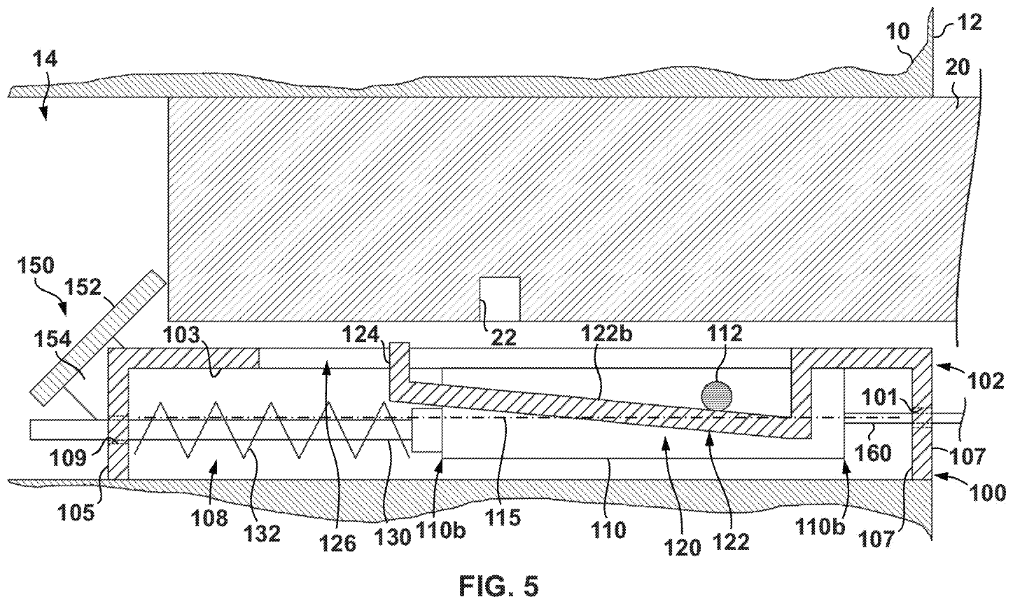

Referring now to FIG. 5, when one wishes to remove peripheral device 20 from cavity 14, an elongate member 160 is inserted through an aperture 101 in wall 107 of frame 102 to thereby engage with the second end 110b of block 110. The elongate member 160 may comprise any suitable device, such as, for instance, a straightened paper clip, elongate rod, punch, key, etc. In addition, the aperture 101 may be externally visible along the housing 12 of electronic device 10 (see e.g., FIGS. 1 and 2). Thus, in some examples, the wall 107 of frame 102 may form a portion of the outer surface of the housing 12 of electronic device 10. In some examples, wall 107 may be disposed internal to electronic device 10, and a corresponding hole or aperture (not shown) may extend through the housing 12 of electronic device 10 that is aligned with (or encompasses) the aperture 101 in wall 107, so that the elongate member 160 may be inserted therethrough.

As a result, when an axially oriented (e.g., with respect to axis 115) force is exerted on the block 110 via the elongate member 160, the block 110 is translated axially within receptacle 108 along planar base surface 103 toward wall 105 and away from wall 107, against the bias of biasing member 132. The axial displacement of block 110 causes the arms 112 to slidingly engage with the second sides 122b of ramped surfaces 122 of latches 120 so as to withdraw the foot 124 of each latch 120 from the recess(es) 22 of peripheral device 20 and therefore allow the removal of peripheral device 20 from cavity 14. Referring briefly again to FIG. 3, the displacement of block 110 along planar base surface 103 is generally supported by the sliding engagement of arms 112 within slots 113 extending in walls 104, 106 of frame 102.

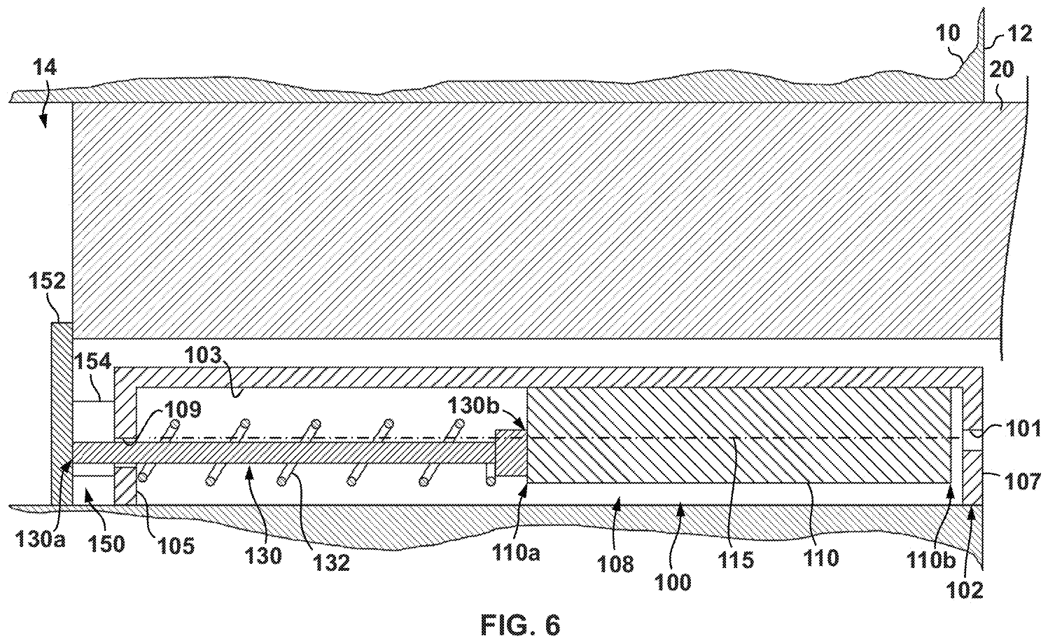

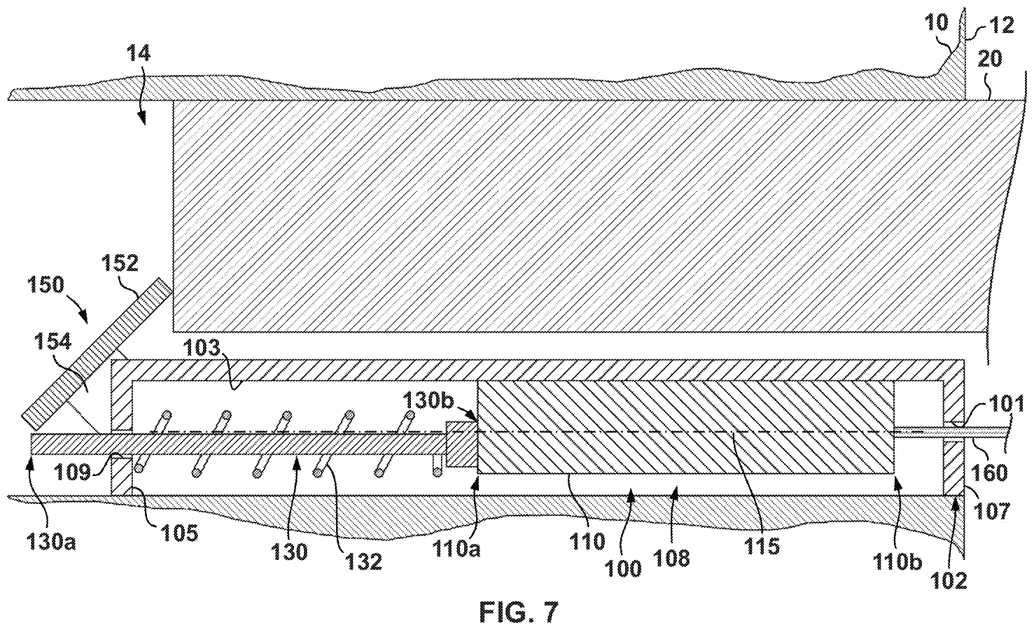

Referring now to FIGS. 6 and 7, when the block 110 is axially displaced (e.g., with respect to axis 115) along planar base surface 103, via the elongate member 160 as previously described, the rod 130 is also axially translated within receptacle 108 so that first end 130a of rod 130 is forced axially outward and through aperture 109 in wall 105. The axial translation of rod 130 causes engagement member 152 to ejector 150 to rotate about the pinned connection 156 on arms 154 (see e.g., FIG. 3) so that engagement member 152 pushes or urges peripheral device 20 outward from cavity 14. Thus, an axial translation of block 110 via elongate member 160 both withdraws the feet 124 of latches 120 from recess 22 of peripheral device 20, and rotates engagement member 152 of ejector 150 so as to force or push peripheral device 20 from cavity 14 of electronic device 10 during operations.

Referring now to FIGS. 4 and 6, once the axial load provided to block 110 and rod 130 via elongate member 160 is removed, the bias provided by biasing member 132 as well as the bias provided by ramped portion 122 of latches 120 forces block 110 and rod 130 to translate axially toward wall 107 of receptacle 108. As rod 130 and block 110 translate axially toward wall 108 of receptacle 108, the feet 124 of latches 120 are once again biased into cavity 14, and the engagement member 152 of ejector 150 is allowed to rotate about pinned connections 156 to its original position (e.g., such as shown in FIGS. 4 and 6).

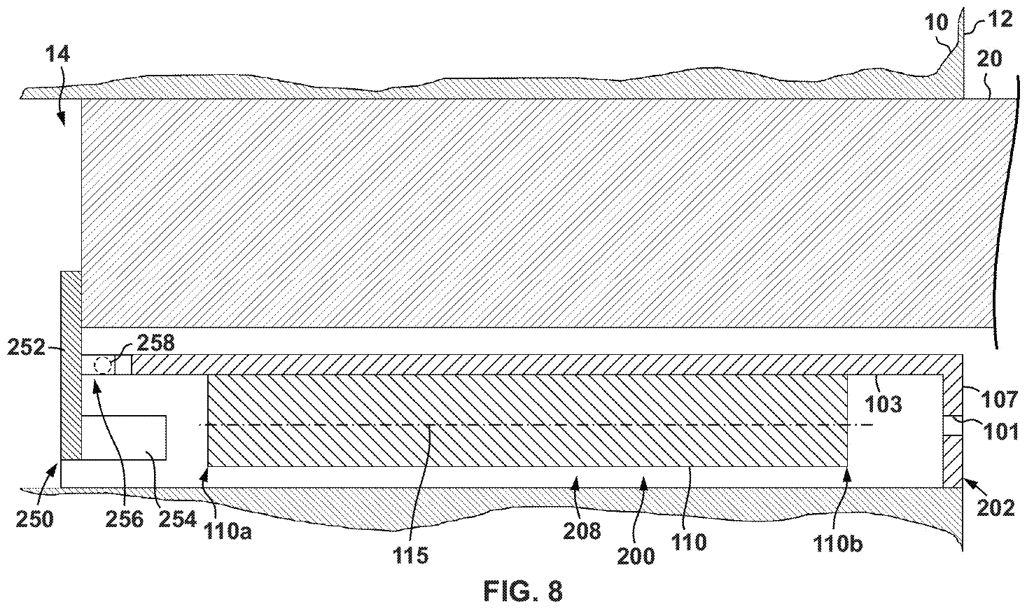

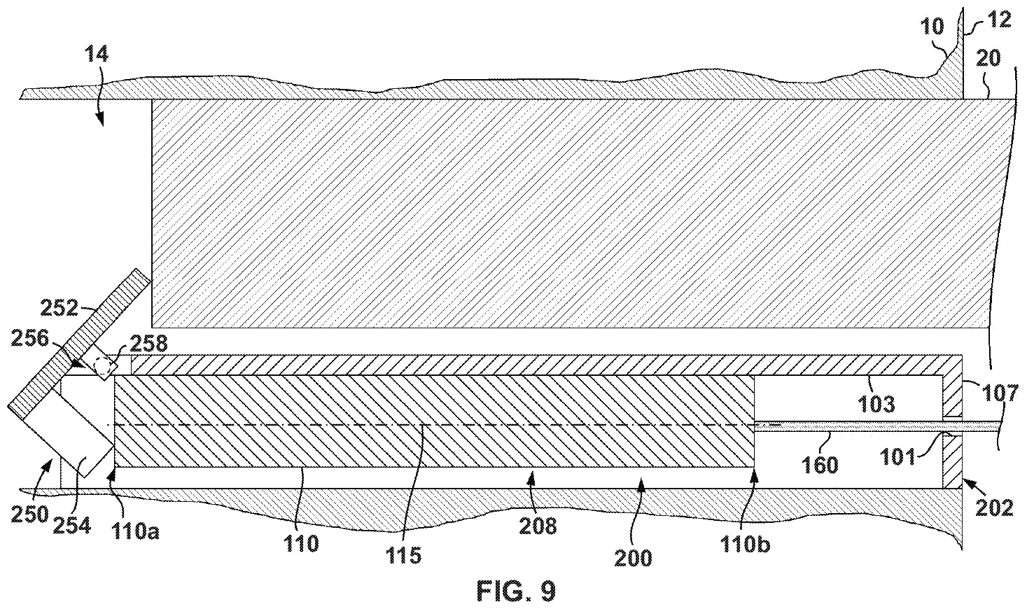

In some examples, the rod 130 and basing member 132 are omitted, and the block 110 may engage directly with the ejector 150 during operations. For instance, reference is now made to FIGS. 8 and 9, which show an example latching assembly 200 that may be used in place of latching assembly 100 (see e.g., FIGS. 3-7). Generally speaking, latching assembly 200 includes the latches 120 that are biased into engagement with the recess(es) 22 in peripheral device 20 during operations as previously described above (see e.g., FIGS. 1-7). However, the rod 130 and biasing member 132 are omitted, the frame 102 is replaced with a frame 202, and the ejector 150 is replaced with an ejector 250.

As is described above for frame 102, frame 202 is a generally rectangular cup shaped member that includes the planar base surface 103, walls 104, 106 (not shown, see e.g., FIGS. 3), and 107, and apertures 126 (not shown). In addition, latches 120 (not shown, see e.g., FIG. 3) are coupled to frame 202 in the manner shown and described above for frame 102; however, these features are not shown in FIGS. 8 and 9 so as to simplify the figures. Further, the wall 105 from frame 102 (see e.g., FIGS. 4-7) is generally omitted from frame 202.

The ejector 250 includes an engagement member 252 and a cam 254 coupled to engagement member 252. The ejector 250 is pivotably coupled to the frame 202 on a side opposite to the walls 107 via a pinned connection 256 which comprises a shaft 258. The shaft 258 may extend from ejector 250 or frame 202 in various examples.

During operations, a peripheral device 20 may be inserted within cavity 14 so that latches 120 engage with recess(es) 22 in peripheral device 20 (see e.g., FIGS. 4 and 5) in the manner described above. When one wishes to remove peripheral device 20 from cavity 14, elongate member 160 is inserted through aperture 101 in wall 107 of frame 102 to thereby engage with the second end 110b of block 110 in the manner described above. As a result, when an axially oriented (e.g., with respect to axis 115) force is exerted on the block 110 via the elongate member 160, the block 110 is translated axially within receptacle 108 away from wall 107, which disengages or withdraws the feet 124 of latches 120 out of recess(es) 22 of peripheral device 20 as described above (see e.g., FIGS. 4 and 5). In addition, the axial displacement of block 110 causes first end 110a of block 110 to engage or abut the cam 254 of ejector 250 such that both cam 254 and engagement member 252 are rotated about the shaft 258 of pinned connection 256. The rotation of engagement member 252 about shaft 258 causes engagement member 252 to engage with peripheral device 20 and therefore forces or urges peripheral device 20 out of cavity 14.

In some examples, the ejector 250 may be rotationally biased about shaft 258, so that engagement member 252 is rotationally biased away from the peripheral device 20 during operations. For instance, a torsional spring (not shown) may be disposed about shaft 258. In other examples, shaft 258 may comprise a so-called torsional shaft which resiliently resists torsion.

As described above, the examples disclosed herein include latching assemblies for facilitating relatively simple attachment and detachment procedures for a peripheral device to a host electronic device. Thus, the use of the disclosed latching assemblies may enhance and promote peripheral device use for a host electronic device, so that operations with the electronic device generally improved.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An electronic device, comprising:
a housing including a cavity to receive a peripheral device therein;
a latching assembly disposed within the housing, wherein the latching assembly comprises:
a latch biased toward the cavity to engage with the peripheral device; and
a block, wherein displacement of the block is to slidingly engage the block along the latch and thereby withdraw the latch from the cavity.

2. The electronic device of claim 1, wherein the latching assembly comprises:
a frame; and
an ejector coupled to the frame;
wherein displacement of the block is to rotate the ejector relative to the frame to thereby push the peripheral device out of the cavity.

3. The electronic device of claim 2, wherein the latching assembly comprises a rod that is biased toward the block, and wherein the block is to engage the rod when the block is displayed along the frame to engage the rod with the ejector.

4. The electronic device of claim 2, wherein the displacement member is rotationally biased toward the block.

5. The electronic device of claim 1, wherein the latch comprises a flat spring, wherein the block comprises an arm, and wherein displacement of the block is to slidingly engage the arm along the latch and thereby withdraw the latch from the cavity.

6. The electronic device of claim 1, wherein the latching assembly comprises a frame, wherein the block is disposed within the frame, and wherein the frame comprises an aperture to receive an elongate member therethrough to engage with and displace the block.

7. A system, comprising:
a first device comprising:
a housing;
a cavity in the housing;
a latching assembly disposed within the housing, wherein the latching assembly comprises:
a latch; and
a block; and
a second device to be inserted within the cavity,
wherein when the second device is inserted within the cavity, the latch is to engage with the second device to prevent withdrawal of the second device from the cavity, and
wherein displacement of the block is to slidingly engage the block with the latch to thereby disengage the latch from the second device.

8. The system of claim 7, wherein the latch is biased into engagement with the second device when the second device is inserted within the cavity, wherein the block comprises an arm, and wherein displacement of the block is to slidingly engage the arm along the latch and thereby withdraw the latch from the cavity.

9. The system of claim 7, wherein the latch is to project into an aperture of the second device when the second device is inserted within the cavity.

10. The system of claim 7, wherein the latching assembly comprises:
a frame; and
an ejector coupled to the frame,
wherein displacement of the block is to rotate the ejector relative to the frame to thereby push the peripheral device out of the cavity.

11. The system of claim 10, further comprising a rod that is biased toward the block, and wherein the block is to engage with the rod when the block is displaced along the frame.

12. The system of claim 10, wherein the displacement member is rotationally biased toward the block.

13. The system of claim 7, wherein the latch comprises a flat spring.

14. An electronic device, comprising:
a housing, including a cavity to receive a peripheral device therein; and
a latching assembly disposed within the housing, wherein the latching assembly comprises:
a latch biased toward the cavity to engage with the peripheral device; and
a block including an arm;
wherein the latching assembly is to transition between:
a first position, in which the latch is extended into the cavity; and
a second position, in which the block is displaced within the latching assembly to slidingly engage the arm with the latch to thereby withdraw the latch from the cavity.

15. The electronic device of claim 14, wherein the latch assembly comprises:
a frame; and
an ejector coupled to the frame;
wherein displacement of the block is to rotate the ejector relative to the frame to thereby push the peripheral device out of the cavity.
